(19) United States
(12) Patent Application Publication
(10) Pub. No.: US 2025/0194134 A1
(43) Pub. Date: Jun. 12, 2025

(54) MOS-GATED TRENCH DEVICE HAVING SHALLOW GATE TRENCHES AND DEEP ISOLATION TRENCHES

(71) Applicant: Pakal Technologies, LLC, San Francisco, CA (US)

(72) Inventors: Paul M. Moore, Hillsboro, OR (US); Richard A. Blanchard, Los Altos Hills, CA (US)

(73) Assignee: PAKAL TECHNOLOGIES INC, SAN FRANCISCO, CA (US)

(21) Appl. No.: 19/053,837

(22) Filed: Feb. 14, 2025

Related U.S. Application Data
(62) Division of application No. 17/531,392, filed on Nov. 19, 2021.

(51) Int. Cl. H10D 30/01; H01L 21/265; H01L 21/3065; H01L 21/308; H01L 21/761; H10D 12/00; H10D 12/01; H10D 30/66; H10D 62/10

(52) U.S. Cl. CPC H10D 30/0297; H01L 21/26513; H01L 21/3065; H01L 21/308; H01L 21/761; H10D 12/038; H10D 12/481; H10D 30/665; H10D 30/668; H10D 62/107

(57) ABSTRACT

A trenched, vertical MOS-gated switch is described that uses only three or four masking steps to fabricate. In one embodiment, one mask is used to form first trenches having a first depth, wherein the first trenches are filled with doped polysilicon to form gates to control the conduction of the switch. A second mask is used to form second trenches having a shallower second depth. The second trenches are filled with the same metal used to form the top source electrode and gate electrode. The metal filling the second trenches electrically contacts a top source layer and a body region. A third mask is used to etch the metal to define the source metal, the gate electrode, and floating rings in a termination region surrounding the active area of the switch. An additional mask may be used to form third trenches in the termination region that are deeper than the first trenches.

### CROSS-REFERENCE TO RELATED APPLICATIONS

This application is based on provisional application Ser. No. 63/141,710, filed Jan. 26, 2021, by Paul M. Moore, and also based on provisional application Ser. No. 63/178,195, filed Apr. 22, 2021, by Paul M. Moore and Richard A. Blanchard, both assigned to the present assignee and incorporated herein by reference.

### FIELD OF THE INVENTION

This invention relates to fabrication processes for forming vertical-conduction, insulated-gate power devices, such as MOSFETs, insulated gate bipolar transistors (IGBTs), gate-controlled thyristors, insulated-gate turn off (IGTO) devices, and other types of MOS-gated semiconductor switches that are generally used with high current/high voltage loads and, in particular, to a fabrication process that reduces the mask count and, as a result, simplifies the process and reduces cost per wafer.

### BACKGROUND

Applicant's U.S. Pat. No. 8,878,238, incorporated by reference, discloses a vertical power device which will be used as an example of one of many types of insulated-gate power devices that can benefit from the present invention. An insulated-gate power device from U.S. Pat. No. 8,878,238 will be described in detail, and the invention will later be described as an improved process for forming such a device and other insulated-gate power devices.

Prior art FIG. 1 is a cross-sectional view of a small portion of a vertical power device 10 described in U.S. Pat. No. 8,878,238 that can benefit from the present invention. Although FIG. 1 just shows an edge portion of the cellular power device 10, the invention applies to all areas within the cellular array.

Three cells are shown having vertical gates 143 (e.g., doped polysilicon) formed in insulated trenches 141A. Trench 141B is for a polysilicon connection to all the gates 143 and may not be considered a cell. A 2-dimensional array of the cells forming, for example, strips or a rectangular mesh, may be formed in a common, lightly-doped p− well 107 (acting as a p− base), and the cells are connected in parallel.

N+ regions 129 surround some or all of the gates 143 and are contacted by a top, metal cathode electrode 127 having a cathode terminal 101. The n+ regions 129 may be formed by implantation or by other known dopant introduction methods. The electrode 127 also contacts the p− well 107 outside the plane of the drawing in some or all of the cells.

The vertical gates 143 are insulated from the p− well 107 by an oxide layer 145. The gates 143 are connected together outside the plane of the drawing and are coupled to a gate voltage via a metal gate electrode 109 directly contacting the polysilicon in the trench 141B. A patterned dielectric layer 119 insulates the gate electrode 109 from the p− well 107 and insulates the gates 143 from the cathode electrode 127.

Guard rings 113 near the edge of the die reduce field crowding for increasing the breakdown voltage. The guard rings 113 are contacted by metal 161 and 163, which are insulated from the n− drift layer 106 by field oxide 117.

A vertical npnp semiconductor layered structure is formed. There is a bipolar pnp transistor formed by a p+ substrate 104, an epitaxially grown n− drift layer 106 (acting as an n− base), and the p− well 107. There is also a bipolar npn transistor formed by the n+ regions 129, the p− well 107, and the n− drift layer 106. An n− type buffer layer 105, with a dopant concentration higher than that of the n− drift layer 106, reduces the injection of holes into the n− drift layer 106 from the p+ substrate 104 when the device is conducting. It also reduces the electric field at the anode pn-junction when the power device 10 is reverse biased. A bottom anode electrode 103 contacts the substrate 104, and the top cathode electrode 127 contacts the n+ regions 129 and also contacts the p− well 107 at selected locations. The p− well 107 surrounds the gate structure, and the n− drift layer 106 extends to the surface around the p− well 107.

When the anode electrode 103, having an anode terminal 102, is forward biased with respect to the cathode electrode 127, but without a sufficiently positive gate bias, there is no current flow, since there is a reverse biased vertical pn junction and the product of the betas (gains) of the pnp and npn transistors is less than one (i.e., there is no regeneration activity).

When the gate 143 is sufficiently biased with a positive voltage (relative to the n+ regions 129), such as 2-5 volts, an inversion layer is formed in the silicon adjacent to the gate oxide layer 145, and electrons from the n+ regions 129 become the majority carriers in this silicon region alongside and below the bottom of the trenches in the inversion layer, causing the effective width of the npn base (the portion of the p− well 107 between the n− layers) to be reduced. As a result, the beta of the npn transistor increases to cause the product of the betas to exceed one. This condition results in “breakover,” when holes are injected into the lightly doped n− drift layer 106 and electrons are injected into the p− well 107 to fully turn on the device. Accordingly, the gate bias initiates the turn-on, and the full turn-on (due to regenerative action) occurs when there is current flow through the npn transistor as well as current flow through the pnp transistor.

When the gate bias is taken to zero, such as the gate electrode 109 being shorted to the cathode electrode 127, or taken negative, the device 10 turns off, since the effective base width of the npn transistor is increased to its original value.

The device 10 is intended to be used as a high voltage/high current switch with very low voltage drop when on. The maximum voltage for proper operation is specified in a data sheet for the device 10.

The device 10 is similar to many other types of high current/high voltage insulated-gate power devices in that it is cellular and all the gates are connected together to a single driver.

There are at least eight masking steps used for form the device of FIG. 1 and each requires precise alignment, time, and added cost. The masking steps include:
P− well implant masking
Trench etch masking
N+ source implant masking
P+ guard ring implant masking
Dielectric layer etch masking over active area
Source/gate metal etch masking
Dielectric layer etch masking over termination region; and
Passivation layer etch masking.

The cost of the wafer is largely determined by the number of masks used.

Additionally, after each masked implant, a high temperature diffusion step is performed. Such high temperature cycling can cause defects in existing oxide or in the bulk silicon. The thin trench gate oxide is especially susceptible to defects due to high temperatures, causing leakage and possibly shorts.

What is needed is a fabrication technique for various types of semiconductor MOS-gated switches that reduces the number of masking steps. Also what is needed is a process that uses a fewer number of (or no) high temperature diffusion steps after the trench gate oxide is formed.

Also, what is also needed is a design that can augment a reduced mask fabrication process to increase the breakdown voltage of the device in the termination region surrounding the active area.

### SUMMARY

In one example of a vertical MOS-gated switch, instead of the conventional 8-mask process, the inventive process is performed using a 3 or 4-mask process.

All epitaxial layers are doped either while being deposited or blanket-doped (implanted) without masking.

Trenches are formed by masking and etching dielectric layers after the N+ source region layer is formed.

After the trenches are filled with doped polysilicon (a maskless process), dielectric layers are deposited, masked, and etched in preparation for source and gate electrode metal deposition.

The source and gate metal is then deposited, masked, and etched.

An optional passivation layer is then deposited, masked, and etched to expose the source and gate pads.

As seen, only four masking steps are required. If no passivation layer is needed, then only three masks are required.

In another embodiment, “floating well” (or field limiting ring) trenches in the termination region are made deeper than the gate trenches and require an additional mask. This approach enables various additional functions and benefits.

Various types of MOS-gated devices may be formed with the general process described, including the structure of FIG. 1.

In another aspect of the disclosure, isolated p-body portions are formed in the termination region surrounding the active area by forming deep trenches in the termination area. The trenches in the active area may be shallow (for causing bipolar transistor conduction) or deep (for causing MOSFET conduction). These isolated areas form pnp vertical transistors. These floating p− body regions increase the breakdown voltage in the termination region. Breakdown is preferable in the active area where the metal electrodes are above and below the active area to better conduct the breakdown current with minimum heat dissipation to avoid damage to the device.

Other embodiments are disclosed.

### BRIEF DESCRIPTION OF THE DRAWINGS

FIG. 1 is copied from Applicant's U.S. Pat. No. 8,878,238 and is a cross-section of a vertical switch having insulated trench gates connected in parallel. About eight masks are used to form the device in a conventional way.

FIG. 2 is a cross-sectional view of a vertical MOS-gated device similar to that of FIG. 1 but formed using only four masking steps.

FIG. 3 is a top down view of the active area of a die and the termination region (near the edge of the die).

FIG. 4 illustrates some initial steps in the fabrication process for forming the device of FIG. 2.

FIG. 5 illustrates some intermediate steps in the fabrication process for forming the device of FIG. 2.

FIG. 6 illustrates additional intermediate steps in the fabrication process for forming the device of FIG. 2.

FIG. 7 illustrates additional intermediate steps in the fabrication process for forming the device of FIG. 2.

FIG. 8 illustrates additional intermediate steps in the fabrication process for forming the device of FIG. 2.

FIG. 9 illustrates the final steps in the fabrication process for forming the device of FIG. 2.

FIG. 10 illustrates another embodiment of the invention having deep trenches only in the termination region for spreading the electric field.

FIG. 11 is a dopant profile in FIG. 1 through the p− well and the n− drift region.

FIG. 12 is a dopant profile in FIG. 1 through the n+ source region, the p− well, and the n− drift layer.

FIG. 13 shows the effect of a long diffusion time.

FIG. 14 shows the desirable effect of a short diffusion time.

FIG. 15 is a cross-section of another embodiment of a vertical switch that is formed with a p-type epitaxial layer as the body layer, rather than a mask-implanted p− well. No trenches are formed in the termination region.

FIGS. 16-29 illustrate embodiments where trenches are formed in the termination region for increasing the breakdown voltage in the termination region.

FIG. 16 shows a dopant profile of FIG. 15, or other embodiments, in the active area having steeper gradients, with less overlap, since there are fewer heating/diffusion steps in the fabrication process.

FIG. 17 shows the deposition of an oxide layer and a nitride layer over the p− body layer.

FIG. 18 shows an additional oxide layer and nitride layer deposited and masked to define deep and shallow trench areas.

FIG. 19 shows trench portions etched using RIE.

FIG. 20 shows the oxide layer and nitride layer removed, and the same etch process being used to concurrently form shallow trenches in the active area and deep trenches in the termination region.

FIG. 21 shows gate oxide on the walls of the trenches and polysilicon deposited in the insulated trenches.

FIG. 22 shows the formation of an oxide mask followed by n-type dopant implantation to form n+ source regions in the active area.

FIG. 23 shows a different embodiment, where vertical MOSFETs are formed in the active region, since all trenches are deep and extend into the n− drift layer.

FIG. 24 shows an example of where the n+ source regions are formed by growing an n-type epitaxial layer over the p− body layer, and the n+ layer is then removed over the termination region.

FIG. 25 shows an alternative embodiment where the n+ source regions are formed by an n-type epitaxial layer, and the n+ layer in the termination region is isolated from the n+ source regions in the active area by deep trenches in the termination region.

FIG. 26 illustrates the deposition of the source metal on the top surface of the device, which contacts the n+ source regions in the active area.

FIG. 27 is similar to FIG. 26 except that all the trenches are deep to form vertical MOSFETs in the active area.

FIG. 28 shows the use of isolated metal portions contacting each isolated p− region and its associated polysilicon in an adjacent deep trench in the termination region for forming equipotential rings surrounding the active area.

FIG. 29 shows an all-deep trench version of FIG. 28 so all conduction in the active area is via MOSFETs. Further, FIG. 29 shows portions of the epitaxial n+ layer being contacted by metal in the termination region and shorted to adjacent trenched polysilicon to remove charge from the polysilicon. The various n+ regions and p-epitaxial layer portions in the termination region are isolated by the deep trenches surrounding the active area.

Elements that are the same or equivalent in the various figures may be labeled with the same numeral.

### DETAILED DESCRIPTION

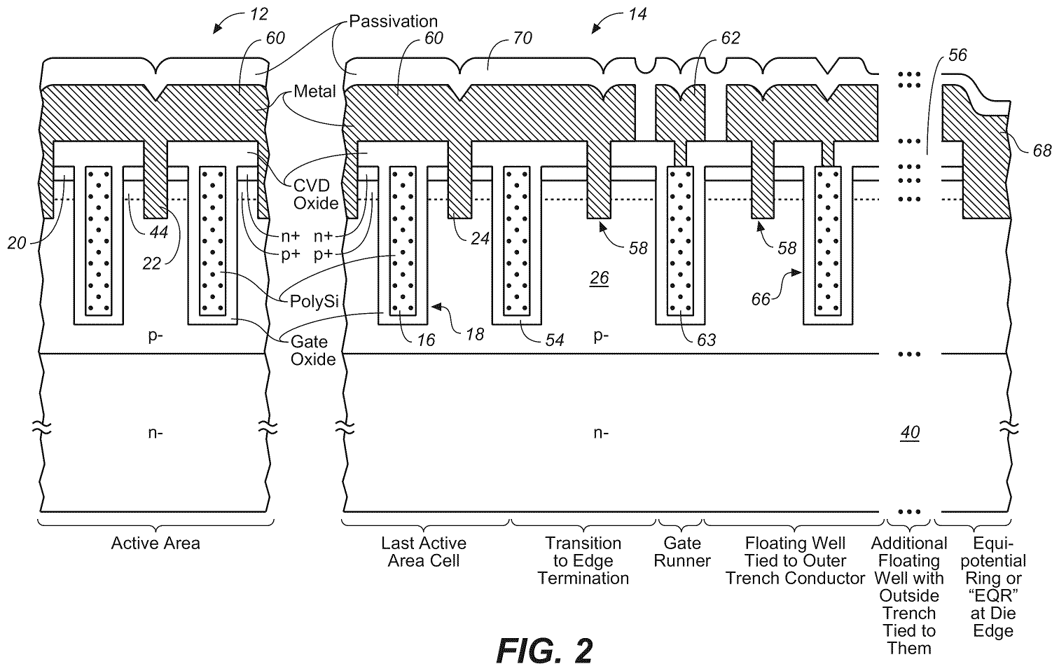

FIG. 2 illustrates an active area 12 of a die and a termination region 14 (near the edge of the die) fabricated using the inventive process. The process will be described with reference to FIGS. 2-9.

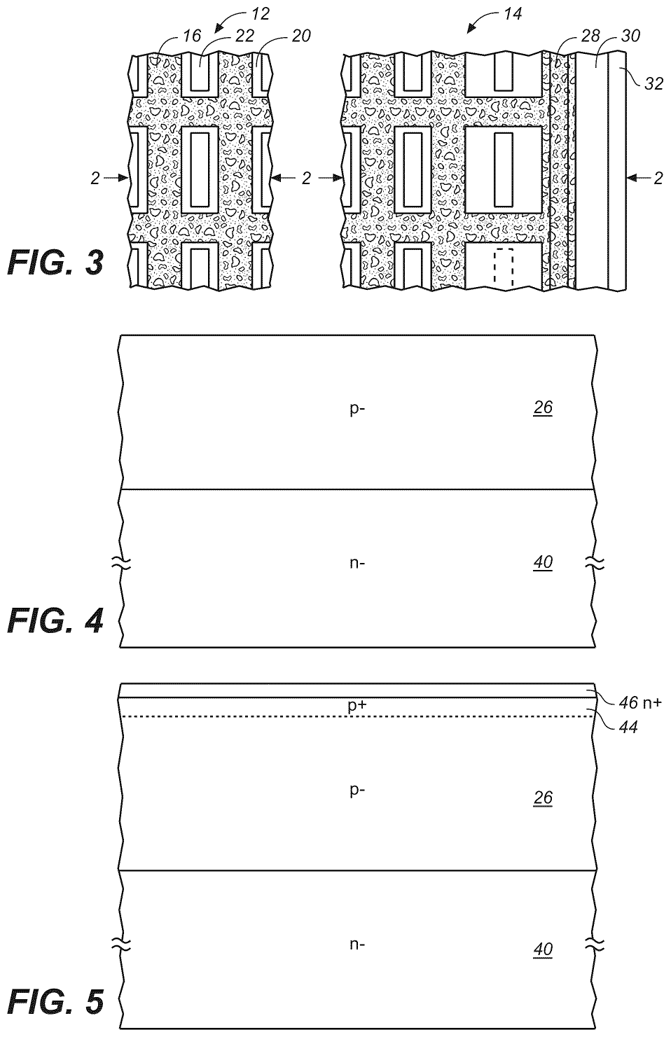

FIG. 3 is a top down view of FIG. 2 with the metal layer removed, where FIG. 2 is taken across line 2-2 of FIG. 3.

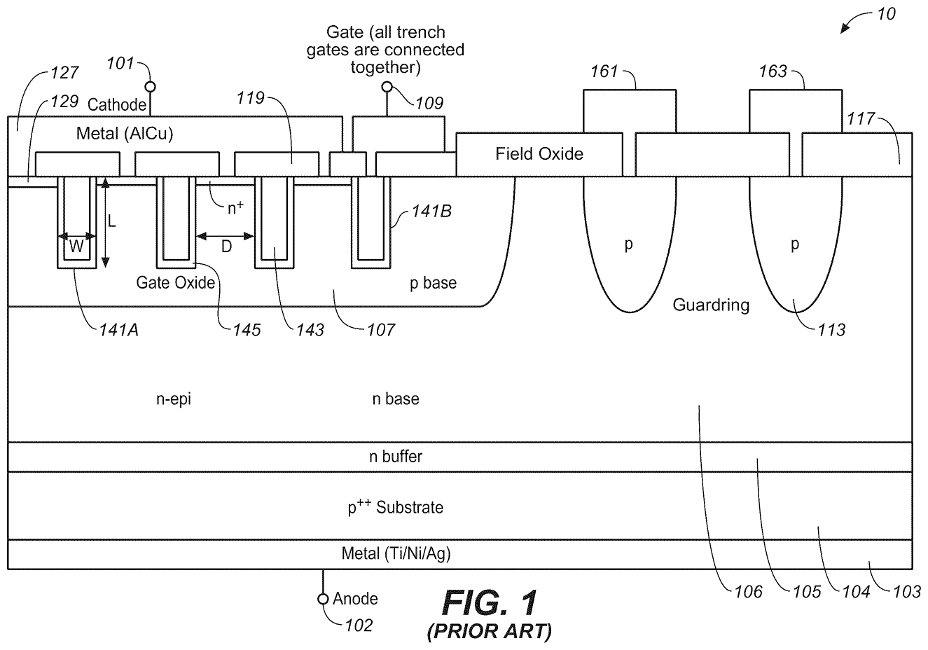

Doped polysilicon 16 within trenches 18 (FIG. 2) are shown as a mesh for forming a two-dimensional array of rectangular cells. The cells are connected in parallel and conduct current vertically to a metal drain (or anode) electrode on the bottom of the die, such as the electrode 103 in FIG. 1. For some devices, the bottom electrode may be referred to as an anode electrode.

The tops of semiconductor n source regions 20 (for the active area 12) are shown surrounding a shallow trench 22 that contains source metal connectors 24 extending into the P− body region 26 (FIG. 2), for shorting the source to the p− body region 26.

As shown in FIG. 3, an opening 28 surrounding the active area 12 of the die exposes the polysilicon 16 for being contacted by the gate metal.

Closer to the perimeter of the die is shown a single ring of a shallow trench 30 for being filled with metal, where there may be additional identical shallow trenches filled with the metal, for forming separate floating equi-potential rings for spreading the electric field.

The die edge 32 is shown (although there may be additional floating rings of p− well material around the perimeter).

The cells may instead be parallel linear cells, hexagonal cells, square cells, or other shaped cells.

The process for forming the device of FIGS. 2 and 3 will now be described with reference to FIGS. 4-10.

In FIG. 4, a starting wafer 40 may be n-type, depending on the device to be formed. The substrate may instead be p-type. The bottom of the wafer may be heavily doped n+ or p+ and then metallized for forming an anode or drain electrode. In the particular device of FIG. 1, the substrate 104 is p+ type with an anode electrode 103 formed on the bottom.

The wafer in FIG. 2 is typically purchased already doped N-type.

Next, as also shown in FIG. 4, an epitaxially grown p− body region 26 is formed. The doping may be during the epi growth, or p-type dopants may be blanket implanted and diffused. No masking steps are required. Since no masking is used, the p− body region 26 may be a continuous layer across the die, unlike the “mask-implanted” p− well 107 in FIG. 1.

Next, as shown in FIG. 5, additional p-type dopants are implanted and diffused into the top surface of the p− body region 26 to form p+ contact regions 44. Although a p+ continuous layer is initially formed, the p+ layer will be segmented by the later formation of trenches.

Next, as shown in FIG. 5, n-type dopants are implanted and diffused into the top surface of the p+ contact regions 44 to form and n+ source layer 46. The n+ source layer 46 will later be segmented by the trenches to form the source regions 20 in FIG. 2.

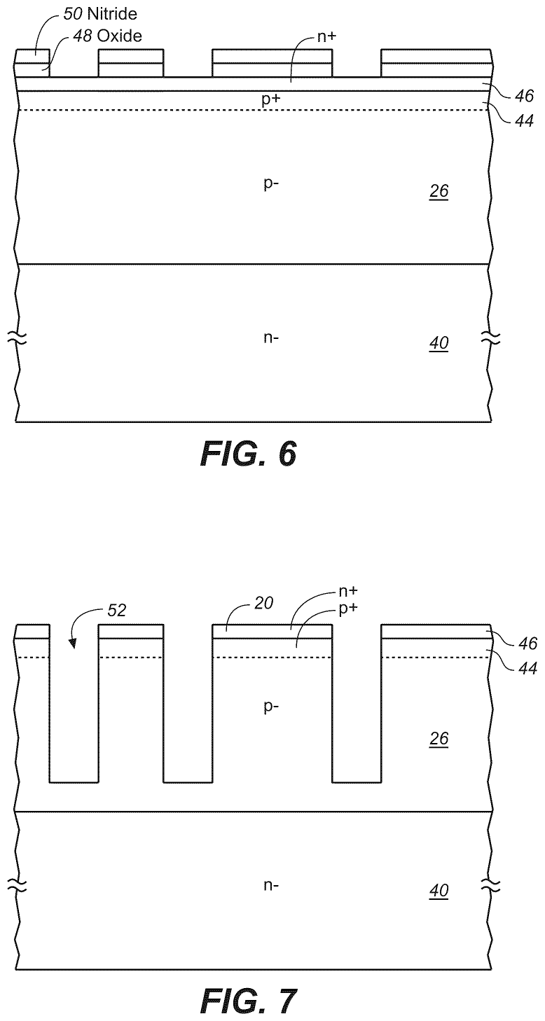

Next, as shown in FIG. 6, a dielectric layer is formed by growing a thermal oxide layer 48, followed by depositing a silicon nitride layer 50. The dielectric layer is then masked and etched, as the first masking step, to define the gate trenches and termination region trenches that will be filled with polysilicon.

Next, as shown in FIG. 7, the trenches are etched using RIE, and the masking layer is removed. To protect the trenches, a sacrificial oxide layer may be grown over the exposed silicon, followed by the removal of the silicon nitride layer 50 and the thermal oxide layer 48 in FIG. 6, which also removes the sacrificial oxide.

A thermal oxidation step is then performed to grow thin gate oxide 54 on the exposed silicon surfaces in the trenches 52.

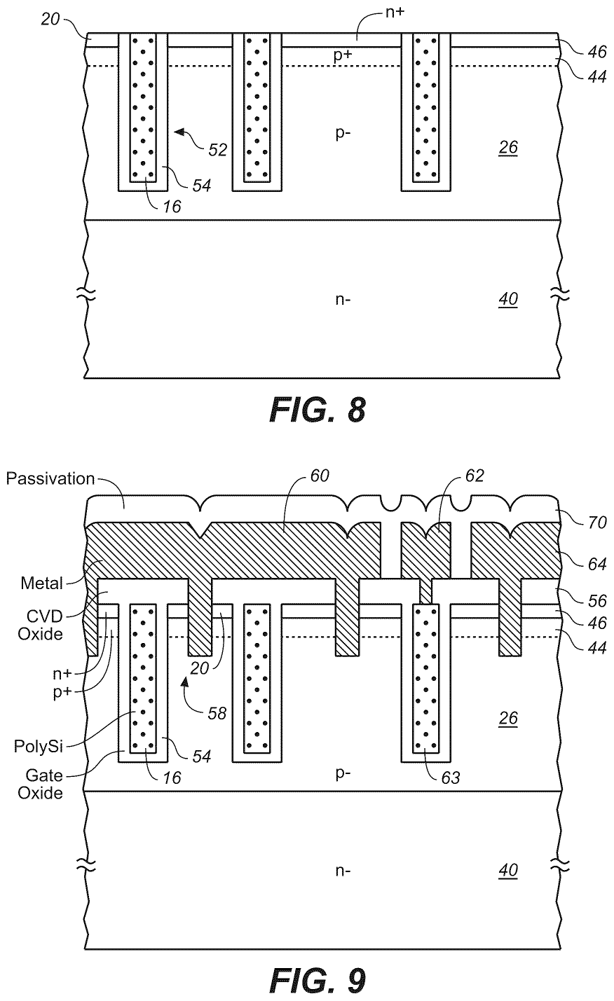

Doped polysilicon 16 is then blanket-deposited to fill the trenches. The polysilicon and the thermal oxide on the top surface of the wafer are then blanket-etched away, leaving the gate oxide and polysilicon only in the trenches 52, shown in FIG. 8. No masking steps are used.

In FIG. 9, a chemical vapor deposition (CVD) process is used to deposit a layer of oxide 56, and the oxide 56 is densified using a conventional process to further harden it and increase its dielectric strength.

Next, a contact mask is used to define areas of the oxide 56 and underlying semiconductor material to be etched to form the shallow trenches 58. Some of the shallow trenches 58 will be used for contacting the p− body region 26 with the source metal 60, and the shallow trenches 58 in the termination region will be used for forming floating wells (rings around the active region) and equi-potential rings. This is only the second mask process.

Next, a layer of metal is deposited and then masked to define the source metal 60, the gate metal 62, the metal 64 in the termination region for contacting the floating wells 66 (FIG. 2), and equi-potential rings 68. This is the third mask process.

Portions of the metal layer filling the shallow trenches 58 contact the sides of the source regions 20 for good electrical contact.

The gate metal 62 contacts a gate runner 63, used for electrically contacting all the polysilicon in the gate trenches.

An optional passivation layer 70 is used to protect the layers and expose the source and gate pads. The passivation layer 70 is then masked and etched to expose the pads. This an optional fourth mask process, which is not used in FIG. 1. Accordingly, the structure of FIG. 1 may be formed using only three masks.

Each floating well 66 (or field limiting ring) comprises a trench filled with polysilicon, where the polysilicon is electrically connected to the p− body region 26 near the inner wall of the trench via the metal layer extending into the shallow trench 58. The number of these floating wells 66 determines the voltage that can be sustained by the device. In the device of FIG. 2, in its off state, the lightly doped p− body region 26 below each floating well 66 is depleted by the applied voltage, guaranteeing that there is no current flow between the rings. The metal bridge between the polysilicon and the p− body region 26 prevents unwanted charge from accumulating in the trenches.

The metal connected to the floating wells 66 may be extended over the silicon surface (as shown in FIG. 2) to act as a field plate.

The equi-potential rings 68 are just separate floating metal rings within the shallow trenches along the perimeter of the die surrounding the active region 12 to further increase the breakdown voltage.

The substrate 40 may have a bottom p+ layer, or the substrate itself may be p+ with an n− epi layer over it, to form a stacked npnp structure for a gate-controlled thyristor or other switch, such as the device of FIG. 1.

If the substrate has a bottom n+ layer and the gate trenches extend all the way into the n− substrate 40, a simple vertical MOSFET is formed, where a positively biased gate creates an n− channel between the n+ source regions 20 and the n− substrate 40 for vertical current flow.

Besides the structure only requiring three or four masks, there is no high temperature step required after the gate oxide 54 is formed, avoiding the possibility of defects from heat cycling.

In another embodiment, instead of shorting the source metal 60 to the p− body region 26 using the shallow trenches, the trench depth could be made even shallower so the source metal 60 only extends into the source regions 46. The source metal 60 directly contacts the sides of the n+ source regions 20. This technique may be used if it is not desired to provide a short to the p− body 26 in every cell.

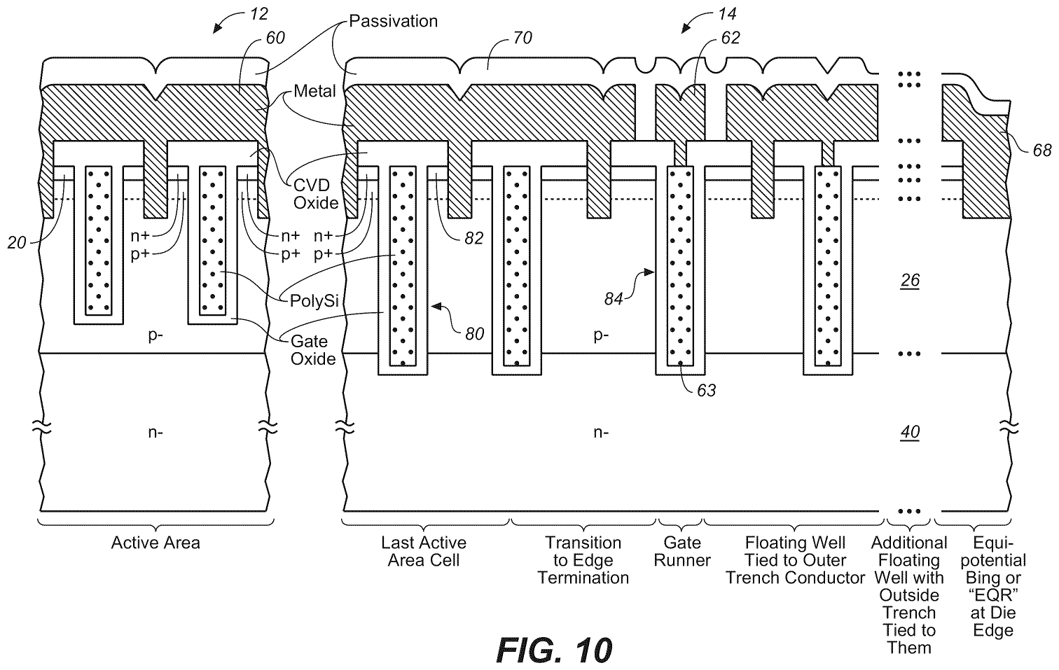

FIG. 10 illustrates a modification to the device of FIG. 2 in that the trenches 80 in the termination region 14 are deep and extend into the n− substrate 40. This causes a positively biased gate (above the threshold voltage) to create a conductive channel between the n+ source region 82 and the n− substrate 40 when the device is on, to cause a small current to flow directly between the source region 82 and the n− substrate 40, unlike the active area 12, where bipolar transistor action is primarily used for current flow. This configuration forms an IGBT at the edge of the active area. Since the bipolar transistor action in the active area 12 results in a lower on-resistance, the relative current flow due to the deep trenches 80 is low but it prevents a build-up of carriers in the termination region for more rapid turn off of the device. It may also increase the breakover voltage of the termination region 14 when compared to the active area 12.

Additionally, the gate runner trench 84 (used for electrically contacting all the polysilicon in the gate trenches) may also be made deep, as shown in FIG. 10.

The deep trenches 80 may also be used to form IGBT devices (insulated gated bipolar transistors) along the perimeter as well as forming floating p− regions due to the continuous trenches 80 effectively isolating rings of the p− body region 26. Such techniques can be applied to any trenched MOS device to achieve various additional functions and capabilities as well as increasing the breakdown voltage and improving turn off time.

The following description is directed to forming an IGBT structure in the termination region surrounding the active area, using a slightly modified process, which results in the IGBT increasing the breakdown voltage in the termination region, so any breakdown will occur in the active area where the metal electrodes above and below the active area can conduct the higher currents during a breakdown event to avoid damage to the device.

Referring back to the prior art FIG. 1, in a conventional fabrication process used to form the device, p-type dopants are implanted in the n− drift layer 106 (using a mask) to form the p− well 107, and n-type dopants are then implanted into the p− well 107 (using another mask) to form the n+ source regions 129. These dopants are diffused using heat, which may adversely affect other materials in the device. The combination of the p− well 107 and the n+ source regions 129 forms a vertical DMOS along the sidewall of the gate trench.

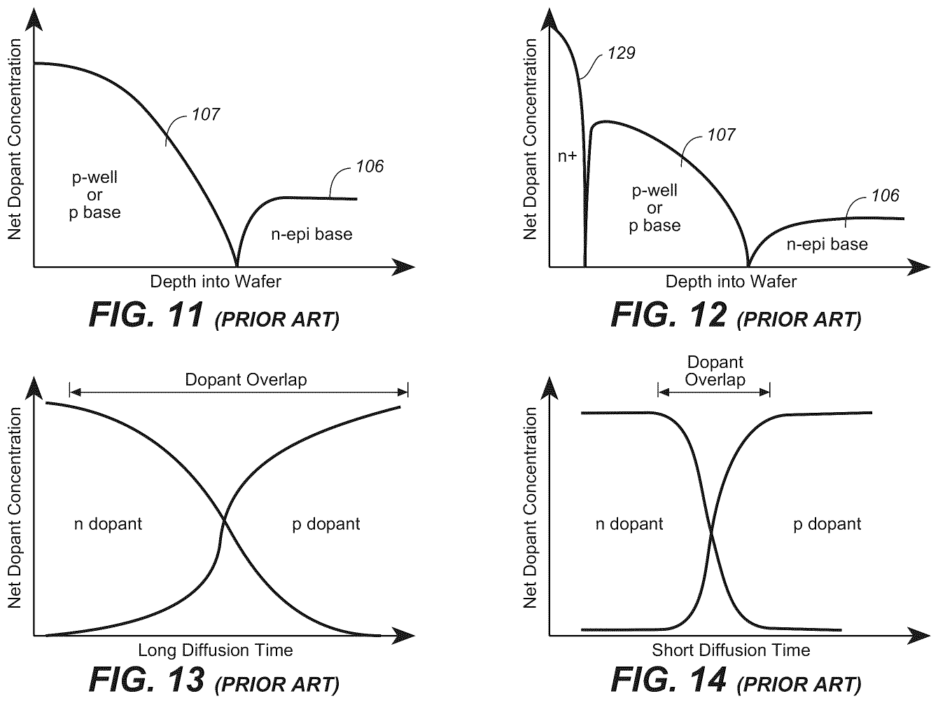

FIG. 11 is a dopant profile in FIG. 1 through the p− well 107 and the n− drift region 106, and FIG. 12 is a dopant profile in FIG. 1 through the n+ source region 129, the p− well 107, and the n− drift layer 106.

FIG. 13 is generic and shows the effect of a long diffusion time, resulting in the both the n-type dopants and the p-type dopants diffusing longer distances, resulting in significant overlap and less predictable device characteristics. FIG. 14 shows the desirable effect of a short diffusion time, where there is less overlap and more predictable device characteristics.

As previously described, the low mask-count technique of the present invention obviates the need for such implantation and multiple dopant diffusion steps, resulting in very well-defined conductivity regions and highly reproducible devices.

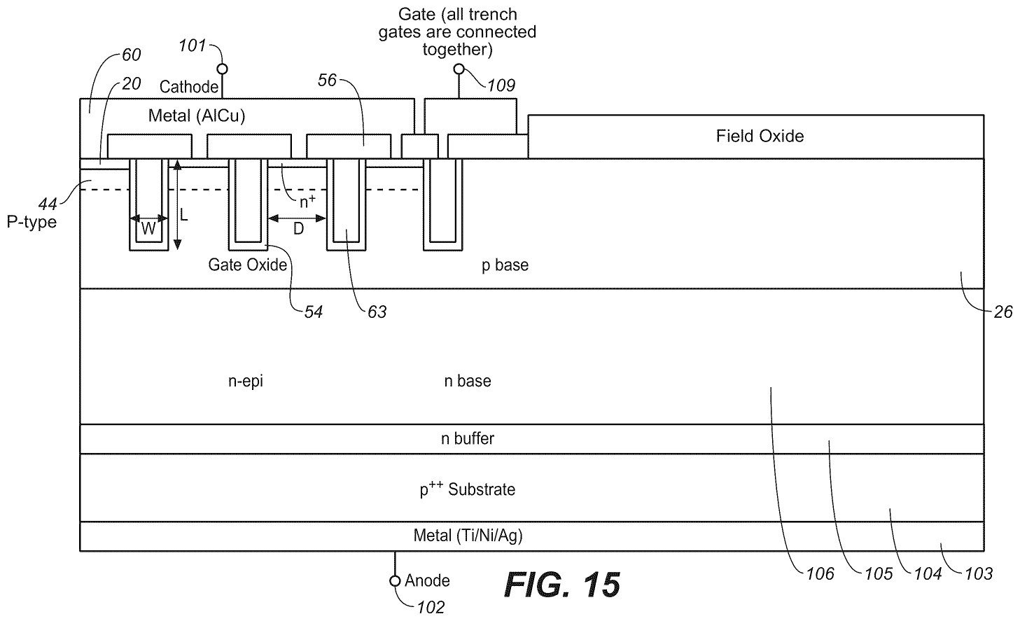

FIG. 15 is a cross-section of a vertical switch that may be formed with a process similar to that shown in FIGS. 2-9, where the p− body region 26 is formed without masking. FIG. 15 differs from the device of FIG. 9 in that the n− drift layer 106 is grown over an n− buffer layer 105, which is grown over a p++ substrate 104, where a metal anode electrode 103 contacts the bottom of the substrate 104. This forms a vertical npnp structure, where a sufficiently positive gate voltage initiates the turn on of the npnp structure for a very low on-voltage, as previously described. FIG. 15 also differs from FIG. 9 in the metal-to-source contact structure.

The combination of time and temperature that a wafer sees during the epitaxial deposition process can be quite small compared to that used in the formation of a p− well using the conventional selective (masked) dopant introduction and diffusion. This difference means that it is possible to have a smaller effect on the doping concentrations in regions that are already present when the epi p− well process is used to fabricate a p− well.

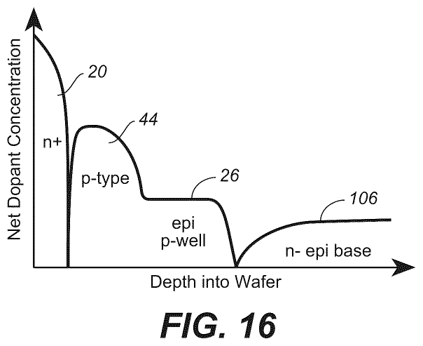

This smaller effect on previously existing dopant profiles means that dopant profiles with steeper gradients that have less overlap can be formed, as shown in FIG. 16, where the relative dopant concentrations are shown for the n+ source regions 20, the p+ contact regions 44, the p− body region 26, and the n− drift layer 106 (also referred to as an n− epi base).

The doping profile of the epi p− body region 26 can be varied greatly. It is possible to grow a p− body region with a uniform doping profile or one with a vertical variation in dopant atom concentration throughout the epitaxial layer.

An epi p− body region 26 with a uniform vertical doping concentration is of particular interest, since it can be used in combination with a more heavily doped p+ body contact regions 44 (FIG. 15) and an n+ source region 20 to produce the structure shown in FIG. 15. The presence of the shallow, more heavily doped p+ body contact regions 44 below the n+ source regions 20 allows the VT (turn-on voltage threshold) of the n-channel MOSFET along the sidewall of the trench to be set by the net p− type dopant concentration that is from both the epi p− body region 26 and the p+ body contact region 44. The remainder of the epi p− body region 26 region that is adjacent to the gate has its surface inverted before the VT of the MOSFET is reached.

The IGTO structure of FIG. 15 shows the use of an n− drift layer 106 and an n-type buffer layer 105, both of which are epitaxially grown over a p++ substrate 104. It is also within the scope of this invention to use an n-type starting wafer and to introduce both n-type and p-type dopant atoms to form the n-type buffer layer 105 and a p+ emitter layer on the back of the wafer. This structure is referred to as a “field stop”, “thin anode”, or “transparent emitter” structure.

The use of the epi p− body region 26 may impact the remainder of the IGTO or IGBT. Specifically, it is no longer possible to use diffused “field-limiting rings” to obtain the needed high voltage breakdown in the termination region. To address this concern, a new high voltage termination structure that is compatible with the epi p− body region process is described below.

The process flow described below provides trenches having two different depths. The shallow trenches in the active region of the IGTO are the same as in the above-described IGTO process. The deeper trenches in the termination region provide isolated p-type regions which, with the correct geometry, can be used as field limiting rings.

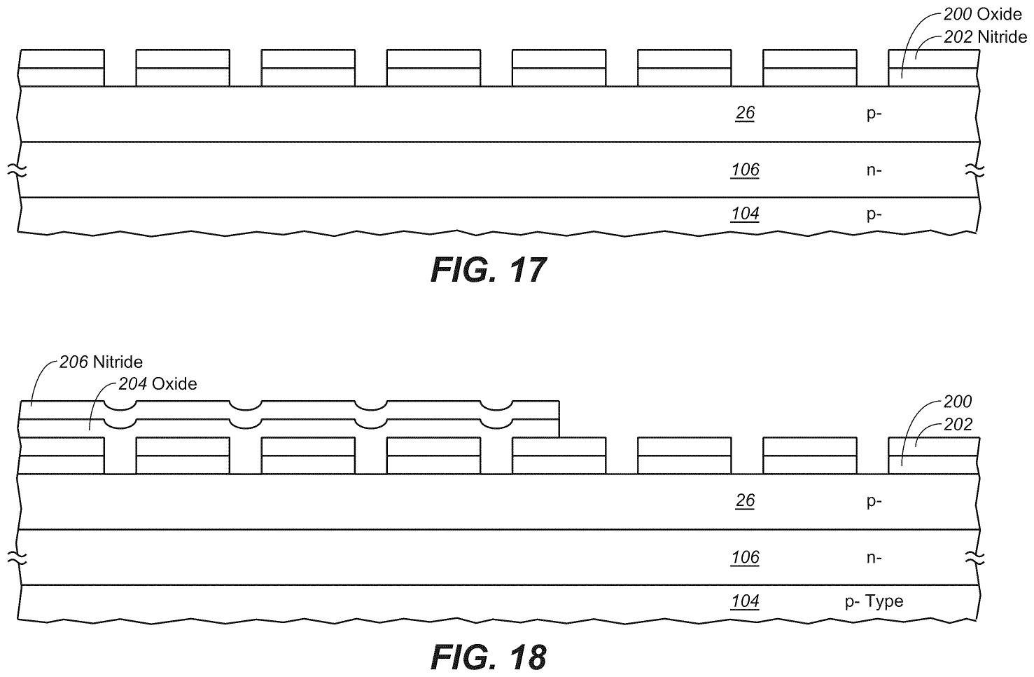

FIG. 17 shows the deposition of an oxide layer 200 and a nitride layer 202 over the p− body layer 26. The layers are then masked and etched to define trench areas.

In FIG. 18, an additional oxide layer 204 and nitride layer 206 are deposited and masked to define deep and shallow trench areas.

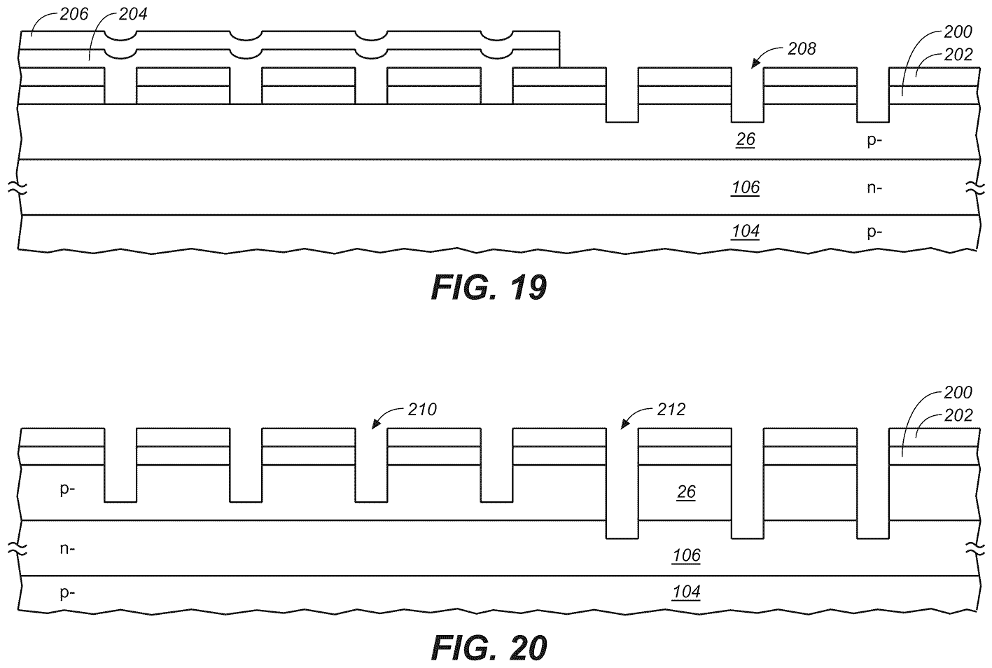

In FIG. 19, partial trenches 208 are etched using RIE, which partially forms the deep trenches in the termination region. The active area is covered by the oxide layer 204 and nitride layer 206.

In FIG. 20, the oxide layer 204 and nitride layer 206 are removed, and the same etch process is used to concurrently form shallow trenches 210 in the active area, and deep trenches 212 in the termination region. The shallow trenches 210 terminate in the p− body layer 26, while the deep trenches 212 terminate in the n− drift layer 106.

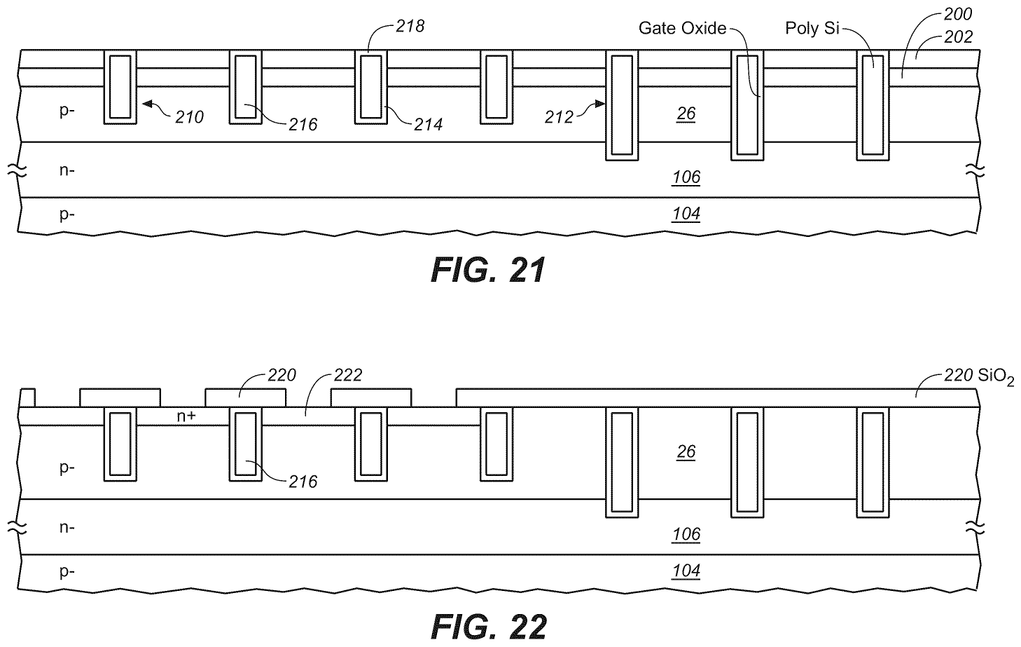

In FIG. 21, a sacrificial oxide layer (not shown) is grown and etched, followed by growing a gate oxide 214 on the walls of the trenches 210 and 212. Polysilicon 216 is then deposited in the trenches and etched back. Another layer of oxide 218 is grown over the polysilicon 216.

In FIG. 22, the oxide layer 200 and nitride layer 202 are removed, the polysilicon 216 is further etched, and a layer of oxide 220 is deposited over the termination region and over the tops of the polysilicon in the active area. N-type dopants are then implanted to form n+ source regions 222 in the active area.

The deep trenches in the termination region create isolated p− regions, which act as field limiting rings to spread the electric field to increase the breakdown voltage in the termination region when the device is off. Thus, breakdown will first occur in the active region, which is better equipped to handle the high currents during breakdown due to the proximity of the metal electrodes. The polysilicon in the deep trenches is floating.

In other embodiments, polysilicon or metal field plates may be connected to one or more of the polysilicon in the deep trenches, or two or more of the filled trenches may be electrically connected together. The spacing and widths of the deep trenches may be selected to improve device performance.

Instead of the n-type dopants being implanted in the surface, the n+ source regions 222 may be an epitaxially grown layer and doped during the growth process.

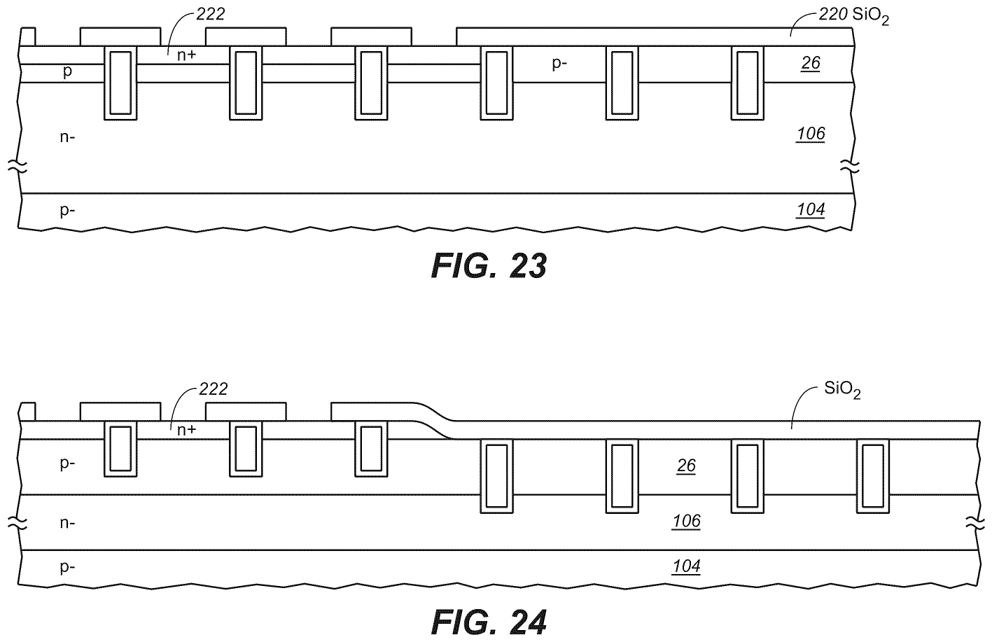

FIG. 23 shows a different embodiment, where vertical MOSFETs are formed in the active region, since all trenches are deep and extend into the n− drift layer 106. The termination region forms a vertical pnp structure. Unlike FIG. 22, where the “shallow” trenches (gates) in the active area terminate in the p-body layer 26, resulting in bipolar transistor action conduction when the device is on, the structure in FIG. 23 results in pure MOSFET conduction when the device is on due to a vertical n− channel being created along the gates between the n+ source regions 222 and the n− drift layer 106. The on-resistance is not as good as the on-resistance of the FIG. 22 embodiment. The deep trenches in the termination region form isolated p-regions for increasing the breakdown voltage in the termination region.

FIG. 24 shows an example of where the n+ source regions 222 are formed by growing an n+ doped epitaxial layer over the entire width of the p− body layer 26 (including in the termination region). The n+ epitaxial layer is then etched away in the termination region.

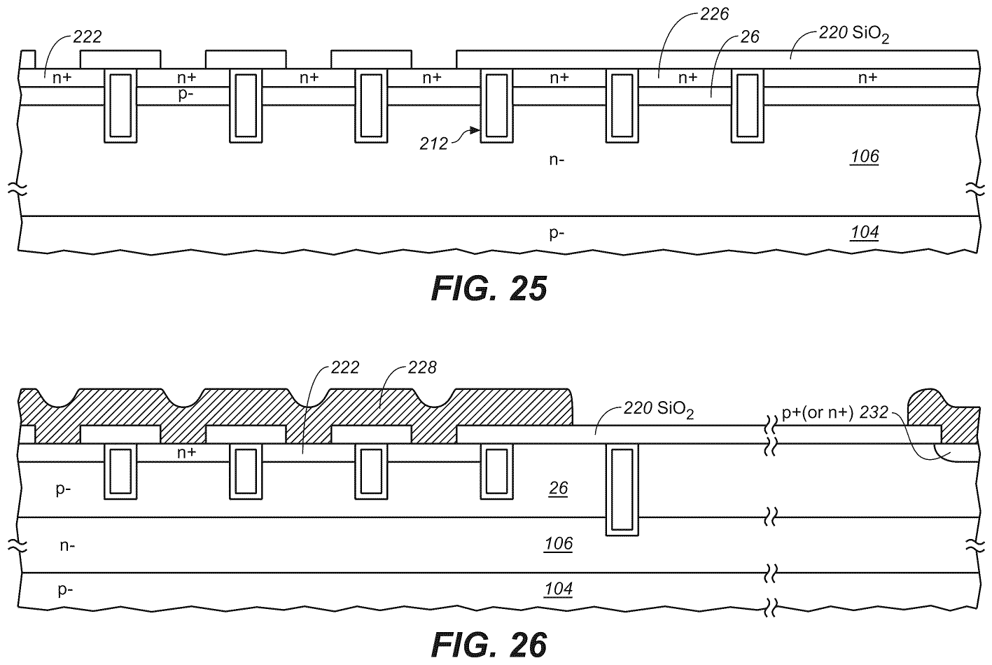

FIG. 25 shows an alternative embodiment where the n+ source regions 222 are formed by an n-type epitaxial layer 226, and the n+ layer 226 in the termination region is isolated from the n+ source regions 222 in the active area by the deep trenches in the termination region isolating the various areas. The n+ layer 226 in the termination region will not be contacted by any source metal (FIG. 26), since there are no openings in the oxide over the termination region.

FIG. 26 illustrates the deposition of the source metal 228 on the top surface of the device, which contacts the n+ source regions 222 in the active area. The layer of oxide 220 in the termination region insulates the source metal 228 from the termination region. In FIG. 26, a p-type or n-type region 232, depending on the type of device, may be used to electrically contact the outer isolated region in the termination region, along the scribe line, to form an equi-potential ring surrounding the device at the edge of the die. The region 232 may be biased at the same voltage as the bottom electrode. In FIG. 26, shallow trenches are employed in the active area for bipolar transistor action conduction.

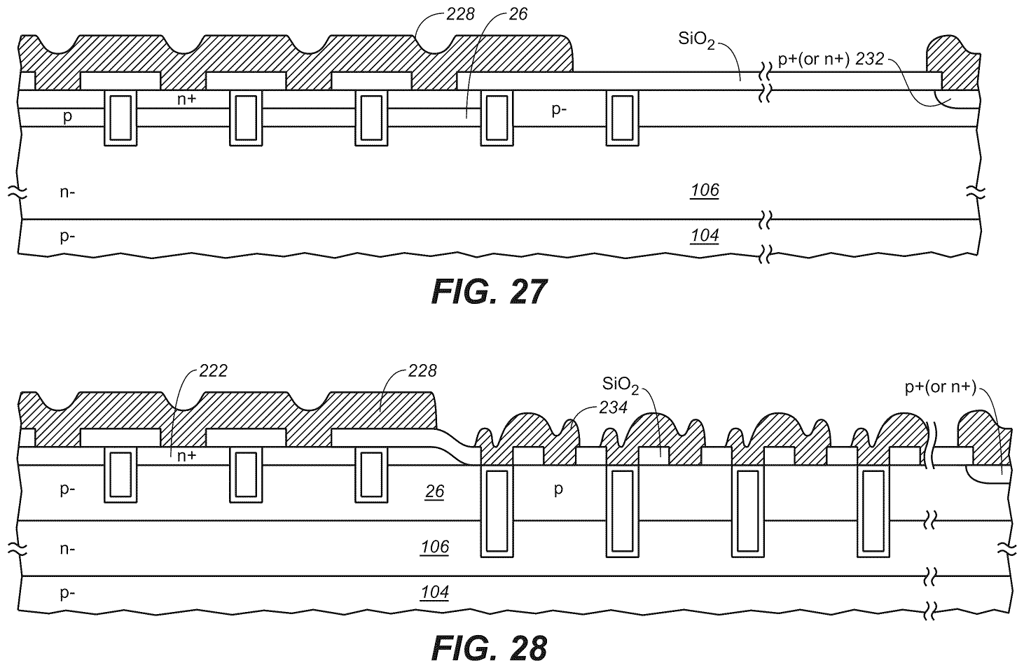

FIG. 27 is similar to FIG. 26 except that all the trenches are deep to form vertical MOSFETs in the active area.

FIG. 28 shows the use of isolated metal portions 234 contacting each isolated p− region and its associated polysilicon in an adjacent deep trench in the termination region for forming equi-potential rings surrounding the active area for increasing the breakdown voltage in the termination region. This technique prevents the accumulation of charge on any trenched floating polysilicon.

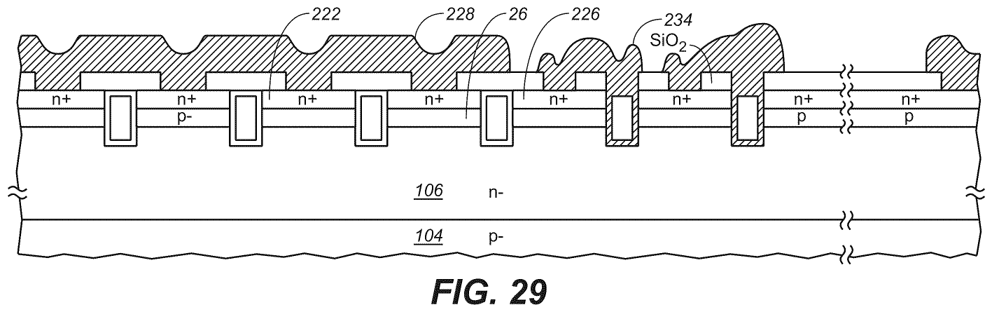

FIG. 29 shows an all-deep trench version of FIG. 28 so all conduction in the active area is via MOSFETs. Further, FIG. 29 shows portions of the epitaxial n+ layer 226 being contacted by metal in the termination region and shorted to adjacent trenched polysilicon to remove charge from the polysilicon.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

1-22. (canceled)

23. A semiconductor structure comprising:
a semiconductor first layer of a first conductivity type, the first layer forming a drift layer;
a semiconductor second layer of a second conductivity type over the first layer, the second layer forming a body region;
a semiconductor third layer of the first conductivity type over the second layer, the third layer forming source regions;
insulated first trenches terminating within the second layer at least partially filled with doped polysilicon, the first trenches having a first depth in an active area to form gates; and
insulated second trenches being deeper than the first depth and terminating within the first layer, the insulated second trenches being at least partially filled with doped polysilicon, the second trenches forming concentric rings around the active area and creating isolated regions of the first layer in a termination region surrounding the active area.

24. The structure of claim 23 wherein the first layer is epitaxially grown over a substrate.

25. The structure of claim 24 wherein the second layer is epitaxially grown over the first layer.

26. The structure of claim 23 wherein the second trenches at least partially filled with the doped polysilicon are electrically floating.

27. The structure of claim 26 further comprising:
a metal ring associated with each of the second trenches, wherein each metal ring is insulated from its associated second trench at least partially filled with the doped polysilicon, wherein each metal ring is electrically floating, and wherein each metal ring electrically contacts an associated isolated region in the second layer to form concentric equipotential rings surrounding the active area.

28. The structure of claim 27 further comprising an outer metal ring contacting the second layer, the outer metal ring surrounding the metal ring associated with each of the second trenches.

29. The structure of claim 28 further comprising:
a source electrode formed on a top of the structure and contacting the third layer in the active area; and
a drain electrode formed on a bottom of the structure to conduct a vertical current through the first layer, the second layer, and the third layer.

30. The structure of claim 29 wherein the outer metal ring is electrically connected to the drain electrode.

31. The structure of claim 23 further comprising a semiconductor substrate of the second conductivity type over which is epitaxially grown the first layer.

32. The structure of claim 23 wherein the third layer is within the active area but not within the termination region.

33. A semiconductor structure comprising:
a semiconductor first layer of a first conductivity type, the first layer forming a drift layer;
a semiconductor second layer of a second conductivity type over the first layer, the second layer forming a body region;
a semiconductor third layer of the first conductivity type over the second layer, the third layer forming source regions;
insulated first trenches terminating within the first layer at least partially filled with doped polysilicon, the first trenches having a first depth in an active area to form gates; and
insulated second trenches terminating within the first layer, the insulated second trenches being at least partially filled with doped polysilicon, the second trenches forming concentric rings around the active area and creating isolated regions of the first layer in a termination region surrounding the active area.

34. The structure of claim 33 wherein the first layer is epitaxially grown over a substrate.

35. The structure of claim 34 wherein the second layer is epitaxially grown over the first layer.

36. The structure of claim 33 wherein the second trenches at least partially filled with the doped polysilicon are electrically floating.

37. The structure of claim 36 further comprising:
a metal ring associated with each of the second trenches, wherein each metal ring is insulated from its associated second trench at least partially filled with the doped polysilicon, wherein each metal ring is electrically floating, and wherein each metal ring electrically contacts an associated isolated region in the second layer to form concentric equipotential rings surrounding the active area.

38. The structure of claim 37 further comprising an outer metal ring contacting the second layer, the outer metal ring surrounding the metal ring associated with each of the second trenches.

39. The structure of claim 38 further comprising:
a source electrode formed on a top of the structure and contacting the third layer in the active area; and
a drain electrode formed on a bottom of the structure to conduct a vertical current through the first layer, the second layer, and the third layer.

40. The structure of claim 39 wherein the outer metal ring is electrically connected to the drain electrode.

41. The structure of claim 33 further comprising a semiconductor substrate of the second conductivity type over which is epitaxially grown the first layer.

42. The structure of claim 33 wherein the third layer is formed within the active area and removed in the termination region.
